(19) United States
(12) Patent Application Publication
(10) Pub. No.: US 2014/0061543 A1
(43) Pub. Date: Mar. 6, 2014

(54) METHOD OF MANUFACTURING NON-FIRING TYPE ELECTRODE USING PHOTOSENSITIVE PASTE

(71) Applicant: TOMONORI OKI, Kanagawa (JP)

(72) Inventor: TOMONORI OKI, Kanagawa (JP)

(73) Assignee: E I DU PONT DE NEMOURS AND COMPANY, Wilmington, DE (US)

(21) Appl. No.: 13/597,519

(22) Filed: Aug. 29, 2012

(51) Int. Cl. G03F 7/20; H01B 1/20

(52) U.S. Cl. 252/500; 430/311

(57) ABSTRACT

A method of manufacturing a non-firing type electrode comprising steps of: (a) applying on a substrate a photosensitive paste comprising, (i) a conductive powder, (ii) an organic polymer comprising acrylic polymer and hydroxypropyl cellulose (HPC) at weight ratio of 5:1 to 2:1, (iii) a photopolymerization initiator, and (iv) a photopolymerizable compound; b) exposing the applied photosensitive paste to light; and (c) developing the exposed photosensitive paste by an aqueous solution, wherein the electrode comprises fine line of width of 5 to 30 μm.

### FIELD OF INVENTION

The present invention relates to a method of manufacturing a non-firing type electrode using a photosensitive paste.

### TECHNICAL BACKGROUND OF THE INVENTION

Electrical devices or substrates which can be damaged by high temperature treatment during manufacturing process need a non-firing type electrode. The term “non-firing type electrode” is defined as an electrode formed without a heat treatment at temperature of 350° C. or higher. When manufacturing such non-firing type electrode in fine pattern, a photolithography method is available.

JP2003162921 discloses a photosensitive conductive composition for the non-firing type electrode that comprises (A) a conductive powder, (B) an organic binder, (C) a photopolymerizable monomer, (D) a photoinitiator, (E) a thermosetting resin and (F) a solvent, wherein the conductive powder of the component (A) is formulated in a ratio of 70-90 mass % in the composition excluding the solvent.

### BRIEF SUMMARY OF THE INVENTION

An objective is to provide a photolithography method of manufacturing a non-firing type electrode, which enables the formation of a fine pattern with a low resistivity.

An aspect of the invention relates to a method of manufacturing a non-firing type electrode comprising steps of: (a) applying on a substrate a photosensitive paste comprising, (i) a conductive powder, (ii) an organic polymer comprising acrylic polymer and hydroxypropyl cellulose (HPC) at weight ratio of 5:1 to 2:1, (iii) a photopolymerization initiator, and (iv) a photopolymerizable compound; (b) exposing the applied photosensitive paste to light; and (c) developing the exposed photosensitive paste by an aqueous solution, wherein the electrode comprises fine line of width of 5 to 30 μm.

Another aspect of the invention relates to a device having the non-firing type electrode manufactured by the method above.

The non-firing type electrode of a fine pattern with a low resistivity can be formed by the present invention.

### BRIEF DESCRIPTION OF THE DRAWINGS

FIG. 1, (A) to (E), explains a photolithography method of manufacturing the non-firing type electrode.

### DETAILED DESCRIPTION OF THE INVENTION

The non-firing type electrode is formed by the method using a photosensitive paste. The photolithography method of manufacturing the electrode and the photosensitive paste is explained respectively below.

### Method of Manufacturing an Electrode

The electrode is formed by applying a photosensitive paste onto a substrate to form a photosensitive paste layer, exposing and developing the photosensitive paste layer.

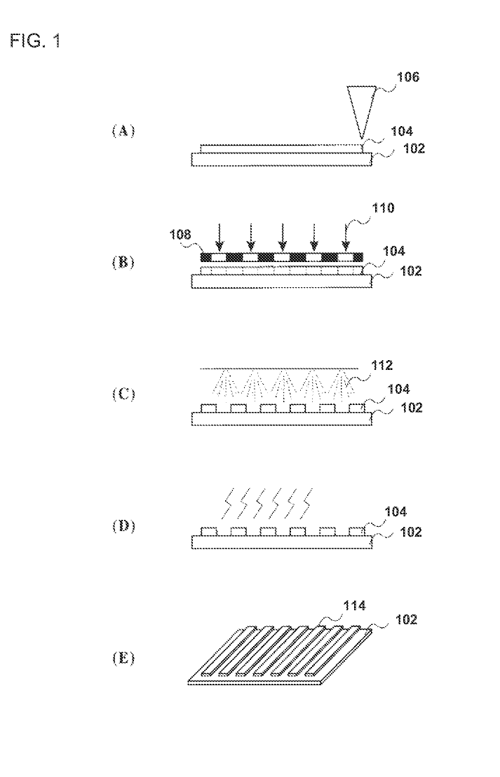

An example of the method of manufacturing the electrode is explained with reference to FIG. 1.

The photosensitive paste is applied onto a substrate 102 by an applying tool 106, for example a screen printing machine, to form a photosensitive paste layer 104 as illustrated in FIG. 1(A). In the event the non-firing type electrode is formed throughout the substrate 102, the photosensitive paste can be applied onto the entire surface of the substrate 102 in an embodiment. In the event part of the electrodes on the substrate 102 consists of the non-firing type electrodes, the photosensitive paste can be applied onto part of the substrate. For example, if a fine pattern is necessary for part of the electrodes, part of the electrodes is formed by the photolithography method and the rest of the electrodes is formed with a heat-curable conductive paste.

The photosensitive paste layer 104 can be multiple layers by applying the photosensitive paste twice or more by using two different paste compositions in another embodiment.

There is no restriction on type of the substrate 102. The substrate 102 can be selected depending on electrical devices; for example, a transparent substrate made of glass or polymer for a touch panel, a semiconductor substrate for solar cell, and a ceramic substrate for capacitor electrode. In an embodiment, the substrate 102 can be selected from the group consisting of a glass substrate, a polymer substrate, a semiconductor substrate, a ceramic substrate and a metal substrate.

When the substrate 102 is a metal substrate or a semiconductor substrate, an insulating layer can be formed on the substrate. When the substrate is a glass substrate, polymer substrate, or ceramic substrate, a transparent electrode can be formed on the substrate. The photosensitive paste can be applied on the insulating layer or the transparent electrode formed on the substrate 102.

The way of applying the photosensitive paste on the substrate can be screen printing that can apply a paste on a substrate 102 in a short time.

The photosensitive paste layer 104 can be optionally dried. When the drying step is carried out, the drying condition can be 50 to 250° C. for 1 to 30 minutes in an oven or dryer.

The photosensitive paste layer 104 is then patterned by being exposed to light. The light 110 such as ultraviolet light is irradiated through a photo mask 108 having a desired pattern so that the exposed area which is same as the desired pattern is cured as illustrated in FIG. 1(B). The gap between the photo mask 108 and the photosensitive paste layer 104 can be 0 to 600 μm.

The exposing condition can be controlled according to photosensitivity of the photosensitive paste and thickness of the photosensitive paste layer 104. For fine patterns, the cumulative exposure is 50 to 2000 mJ/cm² in an embodiment, 100 to 1000 mJ/cm² in another embodiment.

The non-firing type electrode is formed by being developed by an aqueous solution 112 as illustrated in FIG. 1(C). The aqueous solution is an alkaline solution such as a 0.4% sodium carbonate solution in an embodiment. The aqueous solution 112 can be sprayed to the photosensitive paste layer 104 to remove the unexposed area of the photosensitive paste layer 104 so that the cured pattern shows up. In an embodiment, the alkaline solution 112 is sprayed at 0.1 to 0.4 MPa for 5 to 100 seconds.

The patterned photosensitive paste layer 104 after the development is optionally dried as illustrated in FIG. 1(D). The drying condition can be 50 to 250° C. for 1 to 60 minutes in an oven or drier in an embodiment.

The electrode 114 after the development as illustrated in FIG. 1(E) can have width of 5 to 30 μm. In another embodiment the width is 5 to 15 μm, in another embodiment 5 to 13 μm. The thickness of the formed electrode can be 1 to 30 μm in an embodiment, 1 to 20 μm in another embodiment, 1 to 10 μm in another embodiment.

The method of manufacturing the electrode can be applicable to any electrode formed in electrical devices such as solar cell, resistor, capacitor, heater, touch panel, and defogger on an automotive window. In an embodiment, the photolithographic method can be applicable to manufacturing a touch panel that needs a fine line electrode formed without high temperature treatment.

Next, the photosensitive paste composition is explained in detail below. The photosensitive paste comprises at least (i) a conductive powder, (ii) an organic polymer (iii) a photopolymerization initiator, and (iv) a photopolymerizable compound.

### (i) Conductive Powder

The conductive powder is made of any conductive material having electrical conductivity. Such conductive powder can be selected from the group consisting of iron (Fe), aluminum (Al), nickel (Ni), copper (Cu), silver (Ag), gold (Au), molybdenum (Mo), magnesium (Mg), tungsten (W), cobalt (Co), carbon black, graphite, and a mixture thereof. The conductive powder can be selected from the group consisting of Al, Cu, Ag and a mixture thereof in another embodiment.

There is no limitation on shape of the conductive powder. However, a flaky conductive powder, spherical conductive powder or a mixture thereof are generally often used. In an embodiment, the conductive powder is flaky. The flaky conductive powder could increase contact area of the each other, consequently rendering sufficient conductivity to the formed electrode.

The particle diameter (D50) of the conductive powder can be 1 to 10 μm in an embodiment, 1 to 8 μm in another embodiment, 1.5 to 5 μm in another embodiment. The particle diameter within the range can be dispersed well in the paste.

The conductive powder comprising a mixture of two or more of conductive powders with different particle diameters can be used in an embodiment. The smaller particles can fill interspaces of the larger particles so as to enhance the conductivity of the electrode. For example, the conductive powder can be a mixture of a conductive powder with the particle diameter of 0.1 to 3 μm and a conductive powder with the particle diameter of 4 to 10 μm.

The average diameter (D50) is obtained by measuring the distribution of the powder diameters by using a laser diffraction scattering method with Microtrac model X-100.

The conductive powder can be 60 to 89 weight percent (wt %) in an embodiment, 62 to 80 wt % in another embodiment, 65 to 75 wt % in another embodiment, based on the weight of the photosensitive paste. Within the range of conductive powder content, conductivity of the electrode can be sufficient.

### (ii) Organic Polymer

The organic polymer is composed of repeating structural units comprising carbon atoms in the main frame. The conductive powder is dispersed into the organic polymer to form a viscous composition called “paste”, having suitable viscosity for applying on a substrate with a desired pattern. When the organic polymer is solid or not viscous enough to disperse the conductive powder, the solvent that can dissolve the organic polymer can be mixed with the organic polymer to impart a proper viscosity.

The organic polymer contains acrylic polymer and hydroxypropyl cellulose (HPC) at weight ratio of 5:1 to 2:1. The weight ratio of the acrylic polymer and HPC (acrylic polymer: HPC) can be 4:1 to 2:1 in another embodiment, and 3:1 to 2:1 in still another embodiment. When the acrylic polymer and HPC are contained with such ratio, the photosensitive paste can form a fine line having a sufficient conductivity as shown in Example below.

The acrylic polymer having a side chain with a hydroxyl group or a carboxyl group which is soluble in the alkaline solution can render developability for an aqueous solution to the photosensitive paste. The acrylic polymer is homopolymer or copolymer which is polymerized with one or more of compounds selected from the group consisting of acrylic acid, acrylic acid ester, methacrylate acid, methacrylate acid ester, acrylate compound, methacrylate compound, acrylamide compound, and methacrylamide compound. The acrylic polymer can be poly(methacrylic acid-co-methyl methacrylate) (CAS No.: 25086-15-1) in an embodiment. The average molecular weight of the acrylic polymer is 2,000 to 100,000 in an embodiment.

HPC is a partially-etherified cellulose reacted with propylene oxide to replace a part of hydroxy group (—OH) out of three per anhydroglucose unit of the cellulose with 2-hydroxypropoxyl group. CAS No. of HPC is 9004-64-2. HPC can be expressed by the following formula in an embodiment.

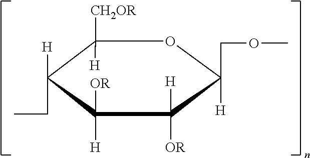

R is H or —[CH₂—CH(CH₃)O]ₘH; m is integer of 1 or larger; n is 100 to 2,500.

Besides the acrylic polymer and HPC, the organic polymer can further contain cellulose, ethylhydroxyethyl cellulose, wood rosin, epoxy resin, phenolic resin or a mixture thereof in an amount of not more than 10 wt % of the total weight of the acrylic polymer and HPC in an embodiment. The total weight of the acrylic polymer and HPC is 90 wt % or more of the organic polymer in an embodiment.

The organic polymer can be 3 to 25 wt % based on the weight of the photosensitive paste.

(iii) Photopolymerization Initiator

The photopolymerization initiator is a chemical compound that decomposes into free radicals when exposed to light. The photopolymerization initiator is thermally inactive at 185° C. or lower, but it generates free radicals when being exposed to an actinic ray. A compound that has two intra-molecular rings in the conjugated carboxylic ring system can be used as the photo-polymerization initiator, for example ethyl 4-dimethyl aminobenzoate (EDAB), diethylthioxanthone (DETX), and 2-Methyl-1[4-(methylthio)phenyl]-2-morpholinopropan-1-one. The photopolymerization initiator can be 0.1 to 5 wt % based on the weight of the photosensitive paste.

### (iv) Photopolymerizable Compound

The photopolymerizable compound is a molecule that may bind chemically to other molecules to form a polymer. The photopolymerizable compound can comprise an organic monomer or an oligomer that includes ethylenically unsaturated compounds having at least one polymerizable ethylene group. Examples of the photopolymerizable compound are ethoxylated (3) trimethylolpropane triacrylate, and dipentaerythritol pentaacrylate. The photo-polymerization compound can be 5 to 15 wt % based on the weight of the photosensitive paste.

### (v) Solvent

The solvent such as Texanol or terpineol can be optionally added to the photosensitive paste to adjust the viscosity of the photosensitive paste to be preferable for applying onto the substrate. The viscosity of the photosensitive paste can be 5 to 300 Pascal second measured on a viscometer Brookfield HBT using a spindle #14 at 10 rpm at 25° C. in an embodiment.

### EXAMPLE

The present invention is illustrated by, but is not limited to, the following examples. Wt % is weight percent based on the weight of the photosensitive paste, unless especially mentioned.

16 wt % of Texanol and 5 wt % of the organic polymer were mixed together at 100° C. until all of the organic polymer had dissolved. The organic polymer was a mixture of Poly(methacrylic acid-co-methyl methacrylate) as an acrylic polymer and HPC (HPC-L, NIPPON SODA CO., LTD.) in different mixing ratio as shown in Table 1.

1 wt % of the photopolymerization initiator and the stabilizer were added to the mixture and stirred at 75° C. The mixture was filtered through a 20 micron filter. 8 wt % of the photolymerizable monomer was added to the filtered mixture and further mixed well. 70 wt % of flake type silver (Ag) powder having D50 of 2 pm was dispersed well into the organic mixture to form the photosensitive paste.

The process was carried out under yellow light. Precautions were taken to avoid dirt contamination, as contamination by dirt during the preparation of the paste and the manufacture of the parts would have resulted in defects.

The photosensitive paste was screen printed through a 350 mesh screen mask onto an indium titan oxide (ITO) transparent electrode that had been already formed on a glass substrate.

The applied photosensitive paste layer was exposed to UV light of 365 nm wave length by using a collimated UV radiation source (exposure: 200 mJ/cm²) through a photo-mask. The photo-mask had L-shaped line patterns having different width of 10 μm, 12.5 μm, 15 μm, 17.5 μm, 20 μm, 25 μm, 30 μm, 35 μm, 40 μm, 45 μm and 50 μm.

The exposed paste layer was placed on a conveyor going in a spray developing device filled with 0.4% sodium carbonate aqueous solution which was kept at a temperature of 30° C., and was sprayed for 40 seconds at 0.2 MPa to the exposed paste layer. After the development the non-firing type electrode of L-shaped having different line width from 10 μm to 50 μm as the photo-mask had was formed. The thickness of the electrode was 5 μm. The non-firing type electrode was dried under the condition 130° C. for 30 minutes in an oven.

### Measurement

Finest Line Width:

The “finest line width” of the electrode was determined as the smallest number of the line width (μm) that could be formed out of 10 μm to 50 μm wide electrodes.

Volume Resistance:

To measure volume resistance, the PDP electrode of line pattern sized 100 μm wide and 5 μm thick and 15 mm long was formed directly on the glass substrate without the ITO. The volume resistivity (Ω·cm) was calculated by the following equation (1). The resistance (Ω) was measured with a multimeter (34401A from Hewlett-Packard Company). The width, the thickness, and the length of the electrode were measured by the microscope having the measurement system.

Volume resistivity (Ω·cm)=Resistance (Ω)×width (cm) of the electrode×thickness (cm) of the electrode/length (cm) of the electrode (1)

### Result

The finest line width was 20 μm or even finer when acrylic polymer:HPC was 4.6:1, 3.3:1 and 2.4:1 as in Example 1 to 3, while such fine line could not formed when acrylic polymer:HPC was 1:0, 6.1:1 and 1.8:1 as in Comparative (Com.) example 1 to 3. When acrylic polymer:HPC was 1.8:1, the photosensitive paste was not developable enough that the cured pattern appeared.

The volume resistivity was 1.3×10⁻⁴ Ω·cm or 1.2×10⁻⁴ Ω·cm when acrylic polymer:HPC was 4.6:1, 3.3:1 and2.4:1 as in Example 1 to 3, while the volume resistivity was 1.4×10⁻⁴ Ω·cm or 2×10⁻⁴ Ω·cm when acrylic polymer:HPC was 1:0 and 6.1:1 as in Com. Example 1 and 2. The volume resistivity of Com. Example 3 was not measurable because the electrode was not formed as mentioned above.

TABLE 1

| | Com. | Com. | | | | Com. |
|---|---|---|---|---|---|---|
| | Example 1 | Example 2 | Example 1 | Example 2 | Example 3 | Example 3 |
| Acrylic | 1:0 | 6.1:1 | 4.6:1 | 3.3:1 | 2.4:1 | 1.8:1 |
| polymer:HPC | | | | | | |
| Acrylic resin | 100 | 86 | 82 | 77 | 71 | 64 |
| (wt %) | | | | | | |
| HPC (wt %) | 0 | 14 | 18 | 23 | 29 | 36 |
| Finest line | 45 | 35 | 25 | 17.5 | 15 | —* |
| width (μm) | | | | | | |
| Volume | 2 | 1.4 | 1.2 | 1.2 | 1.3 | —* |
| resistance | | | | | | |
| (×10⁻⁴ Ω · cm) | | | | | | |

*Not developable.

What is claimed is:

1. A method of manufacturing a non-firing type electrode comprising steps of:
(a) applying on a substrate a photosensitive paste comprising,
(i) a conductive powder,
(ii) an organic polymer comprising acrylic polymer and hydroxypropyl cellulose (H PC) at weight ratio of 5:1 to 2:1,
(iii) a photopolymerization initiator, and
(iv) a photopolymerizable compound;
(b) exposing the applied photosensitive paste to light; and
(c) developing the exposed photosensitive paste by an aqueous solution, wherein the electrode comprises fine line of width of 5 to 30 μm.

2. The method of claim 1, wherein the conductive powder is 60 to 89 wt %, the organic polymer is 3 to 25 wt %, the photopolymerization initiator is 0.1 to 5 wt %, the photopolymerizable compound is 5 to 15 wt %, based on the weight of the photosensitive paste.

3. The method of claim 1, wherein the conductive powder is flaky.

4. The method of claim 1, wherein the average particle size of the conductive powder is 1 to 10 μm.

5. The method of claim 1, wherein the cumulative exposure of the applied photosensitive paste to the light is 50 to 2000 mJ/cm².

6. The method of claim 1, wherein the aqueous solution is sprayed to the exposed photosensitive paste at 0.1 to 0.4 MPa for 5 to 100 seconds.

7. The method of claim 1, wherein the thickness of the electrode is 1 to 30 μm.

8. A device having the non-firing type electrode manufactured by the method of claim 1.
